(19) United States
(12) Patent Application Publication
(10) Pub. No.: US 2025/0226305 A1
(43) Pub. Date: Jul. 10, 2025

(54) CIRCUIT BOARD AND SEMICONDUCTOR PACKAGE COMPRISING SAME

(71) Applicant: LG INNOTEK CO., LTD., Seoul (KR)

(72) Inventors: Chae Young YOU, Seoul (KR); Han Sang KIM, Seoul (KR); Jae Man PARK, Seoul (KR)

(73) Assignee: LG INNOTEK CO., LTD., Seoul (KR)

(21) Appl. No.: 18/852,962

(22) PCT Filed: Mar. 29, 2023
(86) PCT No.: PCT/KR2023/004201

§ 371 Date: Sep. 30, 2024

(30) Foreign Application Priority Data
Mar. 30, 2022 (KR) 10-2022-0039304

(51) Int. Cl. H01L 23/498; H01L 21/48

(52) U.S. Cl. CPC H01L 23/49866; H01L 23/49822; H01L 21/4857

(57) ABSTRACT

A circuit board according to an embodiment includes an insulating layer, and a circuit layer disposed on the insulating layer, wherein the circuit layer includes: a first metal layer disposed on the insulating layer, and a second metal layer disposed on the second metal layer, wherein a side surface of the first metal layer and a side surface of the second metal layer have a step, and a surface roughness of the side surface of the first metal layer is smaller than that of the side surface of the second metal layer.

### TECHNICAL FIELD

An embodiment relates to a circuit board, a semiconductor package, and a method of manufacturing the same.

### BACKGROUND ART

A circuit board is formed by forming a pattern of a circuit line on an electrically insulating substrate with a conductive material such as copper. A circuit board refers to a substrate before mounting an electronic component.

In other words, the circuit board may mean that a mounting position of each component is determined to mount various types of electronic components on a flat plate, and a circuit layer connecting the electronic components is formed.

Meanwhile, signal transmission in the circuit board may be performed through the circuit layer. For example, a semiconductor package has a structure in which an electronic component is mounted on a circuit board. In addition, signal transmission in the semiconductor package is performed through a circuit layer formed on the circuit board. In this case, a signal may include a signal input to an electronic component, a signal output from the electronic component, a signal input from an external substrate, and a signal output to an external substrate, etc.

On the other hand, in order to process a large amount of information at high speed with the high functionalization of portable electronic devices, etc., and the signal is becoming high frequency. In addition, there is a demand for a circuit board suitable for high frequency applications.

A circuit layer of such a circuit board must be capable of transmitting signals without deteriorating a quality of high-frequency signals. For example, the circuit layer of the circuit board should be able to minimize signal transmission loss.

In this case, the transmission loss of the circuit layer in the circuit board is mainly made up of conductor losses caused by metal thin layers such as copper and dielectric losses caused by insulators such as insulating layers.

The conductor losses due to the metal thin film is related to a surface roughness of the circuit layer. That is, as the surface roughness of the circuit layer increases, the transmission loss may increase due to a skin effect.

Accordingly, there is a need for a new circuit board in which surface roughness that can minimize signal transmission loss is applied to the surface of the circuit layer.

### DISCLOSURE

### Technical Problem

An embodiments provides a circuit board, a semiconductor package, and a method for manufacturing the same capable of minimizing signal transmission loss.

In addition, the embodiment provides a circuit board, a semiconductor package, and a method for manufacturing the same suitable for high-frequency applications.

In addition, the embodiment provides a circuit board, a semiconductor package, and a method for manufacturing the same capable of minimizing a depth of an undercut formed at a lower portion of a side surface of a circuit layer.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; and a circuit layer disposed on the insulating layer, wherein the circuit layer includes: a first metal layer disposed on the insulating layer, and a second metal layer disposed on the second metal layer, wherein a side surface of the first metal layer and a side surface of the second metal layer have a step, and a surface roughness of the side surface of the first metal layer is smaller than that of the side surface of the second metal layer.

In addition, an arithmetic average roughness Ra of an upper surface and the side surface of the second metal layer has a range of 0.05 μm to 0.2 μm.

In addition, a ten-point average roughness Rz of an upper surface and the side surface of the second metal layer has a range of 0.1 μm to 1.0 μm.

In addition, a thickness of the first metal layer is smaller than that of the second metal layer.

In addition, the first metal layer has a thickness in a range of 2.5 μm to 3.5 μm.

In addition, the first metal layer includes a first-first metal layer disposed on the insulating layer; and a first-second metal layer disposed on the first-first metal layer, wherein the second metal layer is disposed on the first-second metal layer, and a thickness of the first-first metal layer is greater than that of the first-second metal layer.

In addition, a horizontal distance between an outermost end of the side surface of the second metal layer and an innermost end of the side surface of the first metal layer satisfies a range of 0.5 μm to 4 μm.

On the other hand, a semiconductor package according to an embodiment comprises a plurality of insulating layers; and a plurality of circuit layers respectively disposed on surfaces of the plurality of insulating layers; a first connection part disposed on an uppermost circuit layer among the plurality of circuit layers; and a device disposed on the first connection part, wherein at least one first circuit layer among the plurality of circuit layers includes: a first metal layer; and a second metal layer disposed on the first metal layer, wherein a side surface of the first metal layer and a side surface of the second metal layer have a step, and wherein a horizontal distance between an outermost end of the side surface of the second metal layer and an innermost end of the side surface of the first metal layer satisfies a range of 0.5 μm to 4 μm.

In addition, an arithmetic average roughness Ra of an upper surface and the side surface of the second metal layer has a range of 0.05 μm to 0.2 μm.

In addition, a ten-point average roughness Rz of an upper surface and the side surface of the second metal layer has a range of 0.1 μm to 1.0 μm.

On the other hand, a method of manufacturing a circuit board according to an embodiment comprises: preparing a first insulating layer with a first-first metal layer attached to a surface; forming a through hole passing through the first insulating layer and the first-first metal layer; forming a first-second metal layer on the first-first metal layer and an inner wall of the through hole; forming a mask including an opening on the first-second metal layer; electroplating the first-first metal layer and the first-second metal layer with a seed layer to form a second metal layer filling the opening and the through hole; removing the mask; and performing an etching process to remove a region that does not overlap with the second metal layer in a thickness direction among an entire region the first-first metal layer and the first-second metal layer, wherein the performing of the etching process includes removing a partial region of the first-first metal layer and the first-second metal layer using an etching solution containing an inhibitor of one of a primary amine or an amino acid, an arithmetic average roughness Ra of an upper surface and a side surface of the second metal layer after the etching process has a range of 0.05 μm to 0.2 μm, and a ten-point average roughness Rz of an upper surface and a side surface of the second metal layer after the etching process has a range of 0.1 μm to 1.0 μm.

In addition, the inhibitor of the etching solution contains a primary amine, and the inhibitor including the primary amine is added to the etching solution at a concentration of 0.05 vol. % to 5 vol. %.

In addition, a molecular weight of the primary amine satisfies a range of 43 to 500, and a aliphatic chain of the primary amine has a length of C4-C10.

In addition, the inhibitor of the etching solution comprises one amino acid selected from glycine, glutathione and cysteine, and the inhibitor including the amino acid is added to the etching solution at a concentration of 0.01 vol. % to 3 vol. %.

In addition, the etching solution further includes an ionic surfactant, and the ionic surfactant is added to the etching solution at a concentration in a range of 200 ppm to 700 ppm.

In addition, the ionic surfactant includes a low molecular cationic surfactant.

In addition, a sum of thicknesses of the first-first metal layer and the first-second metal layer has a range of 2.5 μm to 3.5 μm, and the performing of the etching process includes etching the first-first metal layer and the first-second metal layer with an etching thickness set in a range of 3.0 μm to 4.0 μm.

In addition, a side surface of the second metal layer after the etching process has a step with the side surfaces of the first-first metal layer and the first-second metal layer, and a horizontal distance between an outermost end of the side surface of the first metal layer and an innermost end of the first-second metal layer after the etching process satisfies a range of 0.5 μm to 4 μm.

### Advantageous Effects

A circuit layer of the embodiment includes a first metal layer and a second metal layer disposed on the first metal layer. The first metal layer may be a seed layer, and the second metal layer may be an electroplating layer formed with the first metal layer as a seed layer.

In this case, in the embodiment, during a process of forming the circuit layer, an etching process is performed to remove a portion of an entire region of the first metal layer that does not overlap with the second metal layer in a thickness direction. In this case, an etching solution in the embodiment contains an inhibitor and an ionic surfactant of a different type from the inhibitor and ionic surfactant of the etching solution of the comparative example.

Specifically, the inhibitor of the embodiment includes a primary amine or amino acid, not a tetra azole or triazole used in the comparative example. In addition, if a primary amine is used as the inhibitor, a length of an aliphatic chain of the primary amine may be C4-C10. Accordingly, the embodiment allows the first metal layer having a relatively large grain boundary area to be etched faster than the second metal layer while allowing a film (or coating layer) to be formed quickly on a surface of the circuit layer by using an inhibitor having a primary amine group.

In addition, since the aliphatic chain of the primary amine functioning as the inhibitor has a length of C4-C10, an influence of steric hindrance can be minimized. Furthermore, the inhibitor contains only one nitrogen atom having an unshared electron pair that can interact with a copper ion, thereby uniformly forming a low-density film on the surface of the circuit layer.

Accordingly, in the embodiment, a surface roughness of the circuit layer can be lowered compared to the comparative example, and the signal transmission loss resulting therefrom can be minimized.

In addition, the amino acid used as the inhibitor is a zwitterionic, which can act as a buffer in the etching solution. In addition, the amino acid contains a hydroxyl group, and the hydroxyl group can easily control a concentration of H+. Accordingly, stability of the etching solution can be secured, and a depth of an undercut can be reduced while reducing the surface roughness of the circuit layer.

That is, an amino group of the amino acid can act as an inhibitor by forming an inhibitor with copper, while a carboxylic acid at other side can act as a proton buffer. Through this, a concentration of H+ can be easily maintained at an appropriate level. As a result, a surface roughness of the circuit layer can be reduced. In addition, a depth of an undercut of the circuit layer can be minimized.

In addition, a low molecular weight ionic surfactant is used as the ionic surfactant included in the etching solution in the embodiment. As a result, in the embodiment, uniform etching can be performed even on a high-density circuit. That is, the low molecular weight ionic surfactant can quickly function as a surfactant in a small amount compared to a non-ionic surfactant. In the embodiment, the penetration of the etching solution into a region overlapping the second metal layer in a thickness direction can be minimized in a process of etching the first metal layer. Accordingly, the embodiment can minimize the depth of the undercut of the circuit layer.

In addition, the embodiment can prevent damage to the second metal layer by using the low molecular weight ionic surfactant, thereby reducing the surface roughness of the circuit layer.

In conclusion, in the embodiment, an inhibitor including a primary amine or an amino acid and a low molecular weight ionic surfactant are added to the etching solution for etching the first metal layer. Accordingly, the embodiment can reduce the surface roughness of the surface of the circuit layer compared to the comparative example. Accordingly, the embodiment can reduce the signal transmission loss of the circuit layer compared to the comparative example. Accordingly, the embodiment can improve the signal characteristics of the circuit board. Furthermore, the embodiment can provide a circuit board suitable for high frequency applications.

Furthermore, the embodiment includes an undercut of a smaller depth than the comparative example. Accordingly, the embodiment can further improve product reliability of the circuit board.

### DESCRIPTION OF DRAWINGS

FIG. 1 is a cross-sectional view of a circuit board according to a comparative example.

FIG. 2 is a view showing a circuit board according to an embodiment.

FIG. 3 is a view for explaining a layer structure of a circuit layer according to a first embodiment.

FIG. 4 is a view for explaining a layer structure of a circuit layer according to a second embodiment.

FIG. 5 is a view showing a circuit layer according to an embodiment in more detail.

FIG. 6 is a view for explaining a process for forming a circuit layer of a comparative example and an etching solution of layer of a comparative example.

FIG. 7 is a view for explaining a process for forming a circuit layer of an embodiment and an etching solution of an embodiment.

FIG. 8 is a view showing a semiconductor package according to an embodiment.

FIGS. 9 to 18 are views for explaining a method for manufacturing a circuit board according to an embodiment in order of process.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Before describing the embodiment, a circuit board of a comparative example will be described.

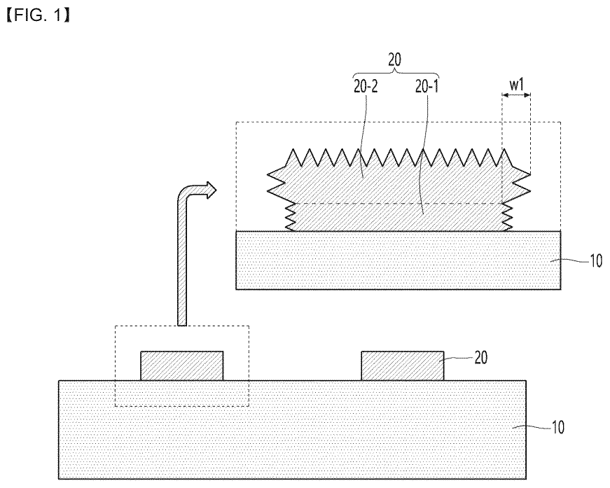

FIG. 1 is a cross-sectional view of a circuit board according to a comparative example.

Referring to FIG. 1, the circuit board of the comparative example includes an insulating layer 10 and a circuit layer 20.

The circuit layer 20 is disposed on a surface of the insulating layer 10.

For example, the circuit layer 20 is disposed on at least one of an upper surface and a lower surface of the insulating layer 10.

The circuit layer 20 includes a plurality of surfaces.

For example, the circuit layer 20 includes a first surface 20U, a second surface 20S1, and a third surface 20S2. The first surface 20U may mean an upper surface of the circuit layer 20. The second surface 20S1 may mean a first side surface or a left side surface of the circuit layer 20. The third surface 20S2 may mean a second side surface or a right side surface of the circuit layer 20. Also, the circuit layer 20 may include a fourth surface or a lower surface contacting an upper surface of the insulating layer 10.

In this case, the first surface 20U, the second surface 20S1, and the third surface 20S2 of the circuit layer 20 have specific surface roughness.

The surface roughness may be applied during a manufacturing process of forming the circuit layer 20. For example, the surface roughness may be applied to the surface of the circuit layer 20 in an etching process of a seed layer constituting the circuit layer 20.

For example, the circuit layer 20 has a multi-layer structure. For example, the circuit layer 20 includes a first metal layer 20-1 and a second metal layer 20-2. The first metal layer 20-1 may mean a seed layer for electroplating the second metal layer 20-2.

The first metal layer 20-1 may have a one-layer structure depending on the manufacturing method of the circuit layer 20, or may have a two-layer structure differently.

For example, when the circuit layer 20 is manufactured by a SAP method, the first metal layer 20-1 may have a one-layer structure corresponding to a chemical copper plating layer.

In addition, when the circuit layer 20 is manufactured by a MSAP method, the first metal layer 20-1 has a two-layer structure including a first layer corresponding to a copper layer or copper foil and a second layer corresponding to a chemical copper plating layer.

In this case, when the circuit layer 20 has a one-layer structure, a thickness of the first metal layer 20-1 has a range of 0.3 μm to 1.5 μm.

In addition, when the circuit layer 20 has a two-layer structure, a thickness of the first metal layer 20-1 has a range of 2.5 μm to 3.5 μm.

In this case, an etching thickness in an etching process for forming the circuit layer 20 is set based on the thickness of the first metal layer 20-1.

For example, the etching thickness of the etching process in the SAP process is set to about 0.6 μm to 1.6 μm. And, the etching thickness of the etching process in the MSAP process is set to about 3 μm to 4 μm.

In this case, the etching process of the seed layer in the process of forming the circuit layer 20 as described above is performed with a thickness greater than 0.1 μm of the etching thickness performed in a general lamination pretreatment process.

In addition, in the process of etching the seed layer, a surface (for example, an upper surface and a side surface) of the circuit layer 20 is also etched together. In addition, the surface of the circuit layer 20 has a relatively high surface roughness by etching the surface of the circuit layer 20.

That is, a specific surface roughness may be applied to the first surface 20U, the second surface 20S1, and the third surface 20S2 of the circuit layer 20 in a process of etching the first metal layer 20-1.

For example, an arithmetic average roughness Ra of the first surface 20U, the second surface 20S1, and the third surface 20S2 of the circuit layer 20 of the comparative example exceeds 0.3 μm. For example, a ten-point average roughness Rz of the first surface 20U, the second surface 20S1, and the third surface 20S2 of the circuit layer 20 of the comparative example exceeds 3.5 μm.

Accordingly, the circuit layer 20 of the comparative example has a problem in that the signal transmission loss is relatively high due to the arithmetic average roughness and the ten-point average roughness of the first surface 20U, the second surface 20S1, and the third surface 20S2. For example, the signal transmission loss increases in proportion to the surface roughness of the circuit layer 20. In addition, the circuit board of the comparative example has a problem in that the signal transmission loss is relatively high due to a skin effect due to the arithmetic average roughness or the ten-point average roughness of the first surface 20U, the second surface 20S1, and the third surface 20S2 of the circuit layer 20. Therefore, the circuit board of the comparative example has a problem in that it is difficult to apply to high frequency applications.

In this case, the surface roughness of the circuit layer 20 is greater in the circuit layer manufactured by the MSAP method, which has a relatively larger etching thickness than the circuit layer manufactured by the SAP method.

Meanwhile, a side surface of the circuit layer 20 of the comparative example has a step.

That is, when the etching process is performed, an etching rate of the first metal layer 20-1 is relatively faster than an etching rate of the second metal layer 20-2. Accordingly, a side surface of the first metal layer 20-1 is positioned closer to an inside of the circuit layer 20 than a side surface of the second metal layer 20-2. In addition, the step is also called an undercut of the circuit layer 20. In this case, the comparative example has a problem that it is difficult to maintain the H+ concentration in the etching solution that etches the circuit layer 20 at an appropriate level, and thus the depth of the step or undercut is relatively large.

Specifically, the circuit layer 20 of the comparative example includes a first metal layer 20-1 and a second metal layer 20-2. In addition, the circuit layer 20 includes an undercut corresponding to the step between the side surface of the first metal layer 20-1 and the side surface of the second metal layer 20-2 in a process of etching the first metal layer 20-1. In addition, a depth of the undercut may mean a horizontal distance from an outermost side of the side surface of the circuit layer 20 to an innermost side of the circuit layer 20. For example, a depth of the undercut means a horizontal distance from an innermost side of a side surface of the first metal layer 20-1 to an outermost side of a side surface of the second metal layer 20-2.

In this case, the depth w1 of the undercut in the comparative example exceeds 5 μm. For example, the depth w1 of the undercut in the comparative example exceeds 6 μm. In addition, the undercut may act as a factor that reduces electrical reliability and physical reliability of the circuit layer. For example, as the depth of the undercut increases, the electrical reliability and physical reliability of the circuit layer may decrease.

In addition, in the comparative example, the surface roughness of the circuit layer 20 is reduced by oxidizing a surface of the circuit layer 20.

For example, in the comparative example, an oxide layer is formed by oxidizing the surface of the circuit layer 20, and a surface roughness of the circuit layer 20 decreases by reducing the oxide layer. However, the adhesive force between the formed oxide layer and the circuit layer 20 is relatively low. Accordingly, in a process of forming the oxide layer, a portion of the oxide layer may be separated from the circuit layer 20. In addition, if the oxide layer is separated from the circuit layer 20, there is a problem that the surface roughness of a corresponding portion is relatively high. In addition, in the process of reducing the oxide layer, there may be a problem that the oxide layer cannot be partially reduced. In addition, if the oxide layer is not partially reduced, there may be a problem that the electrical reliability of the circuit layer 20 is deteriorated.

Meanwhile, if the surface roughness of the circuit layer 20 is recklessly reduced, another problem may occur. For example, a circuit board is manufactured by performing a process of stacking a plurality of insulating layers. In this case, if the surface roughness of the circuit layer 20 decreases, there is a problem that an adhesive force between the circuit layer 20 and the insulating layer (not shown) which is additionally stacked is deteriorated. Accordingly, there may be a problem that the additionally stacked insulating layer is separated from the circuit layer 20.

Accordingly, the embodiment allows the surface roughness of the circuit layer to be lowered compared to the comparative example without performing additional processes. Furthermore, the embodiment allows the depth of the undercut formed in the circuit layer to be lowered compared to the comparative example. Accordingly, the embodiment provides a circuit board and a semiconductor package suitable for high-frequency applications.

### —Electronic Device—

Before describing an embodiment, an electronic device including the semiconductor package of the embodiment will be briefly described. The electronic device includes a main board (not shown). The main board may be physically and/or electrically connected to various components. For example, the main board may be electrically connected to the semiconductor package of the embodiment. Various devices may be mounted on the semiconductor package.

Memory chips such as volatile memory (e.g., DRAM), non-volatile memory (e.g., ROM), and flash memory, application processor chips such as a central processor (e.g., CPU), graphics processor (e.g., GPU), antenna chip, digital signal processor, cryptographic processor, microprocessor, and microcontroller, and logic chips such as analog-digital converters and ASICs (application-specific ICs) can be mounted in the semiconductor package.

For example, at least one of various types of passive devices and active devices may be mounted in the semiconductor package.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a circuit board and a semiconductor package according to an embodiment will be described in detail. Here, the circuit board may refer to a substrate before an electronic device is mounted. In addition, the semiconductor package may refer to a package in which an electronic device is mounted on the circuit board.

FIG. 2 is a view showing a circuit board according to an embodiment.

Referring to FIG. 2, the circuit board may include an insulating layer, a circuit layer, a through electrode, and a protective layer. In this case, although the circuit board is illustrated to have a three-layer structure based on a number of layers of the insulating layer in the drawing, the embodiment is not limited thereto. For example, the circuit board may have two or less layers based on a number of layers of the insulating layer, or may have four or more layers.

The insulating layer may include a first insulating layer 111, a second insulating layer 112, and a third insulating layer 113. The first insulating layer 111 may mean an insulating layer disposed inside a stacked structure of a circuit board. In addition, the second insulating layer 112 may mean an insulating layer disposed on the first insulating layer 111. In addition, the third insulating layer 113 may mean an insulating layer disposed below the first insulating layer 111.

At least one of the first insulating layer 111 and the third insulating layer 112 and the third insulating layer 113 may include a prepreg (PPG). The prepreg may be formed by impregnating a fiber layer in the form of a fabric sheet, such as a glass fabric woven with glass yarn, with an epoxy resin, and then performing thermocompression. However, the embodiment is not limited to this, and the prepreg constituting At least one of the first insulating layer 111 and the third insulating layer 112 and the third insulating layer 113 may include a fiber layer in the form of a fabric sheet woven with carbon fiber yarn.

For example, at least one of the first insulating layer 111, the second insulating layer 112, and the third insulating layer 113 may be rigid or flexible.

At least one of the first insulating layer 111, the second insulating layer 112, and the third insulating layer 113 may have a thickness in a range of 10 μm to 60 μm. Preferably, at least one of the first insulating layer 111, the second insulating layer 112, and the third insulating layer 113 may have a thickness in a range of 12 μm to 50 μm. More preferably, at least one of the first insulating layer 111, the second insulating layer 112, and the third insulating layer 113 may have a thickness in a range of 15 μm to 40 μm.

If the thickness of at least one of the first insulating layer 111, the second insulating layer 112, and the third insulating layer 113 is less than 10 μm, the circuit layer included in an antenna substrate may not be stably protected. If the thickness of at least one of the first insulating layer 111, the second insulating layer 112, and the third insulating layer 113 is greater than 60 μm, the thickness of the circuit board, the semiconductor package, and the electronic device including the same may increase. Also, If the thickness of at least one of the first insulating layer 111, the second insulating layer 112, and the third insulating layer 113 is greater than 60 μm, a thickness of the circuit layer and a thickness of the through electrode may increase correspondingly. In addition, if a thickness of the circuit layer and a thickness of the through electrode increase, the signal transmission loss may increase.

A circuit layer may be disposed on a surface of the insulating layer.

The circuit layer may be disposed on the surface of the insulating layer to transmit a signal in the circuit board.

For example, the circuit layer may be disposed on each surface of the first insulating layer 111, the second insulating layer 112, and the third insulating layer 113.

Specifically, the circuit layer may include a first circuit layer 121 disposed on an upper surface of the first insulating layer 111. Also, the circuit layer may include a first circuit layer 121 disposed on a lower surface of the first insulating layer 111. Also, the circuit layer may include a third circuit layer 123 disposed on an upper surface of the second insulating layer 112. Also, the circuit layer may include a fourth circuit layer 124 disposed on a lower surface of the third insulating layer 113.

Each of the first circuit layer 121, the second circuit layer 122, the third circuit layer 123, and the fourth circuit layer 124 may have a thickness of 10 μm to 25 μm. Preferably, each of the first circuit layer 121, the second circuit layer 122, the third circuit layer 123, and the fourth circuit layer 124 may have a thickness of 12 μm to 23 μm. More preferably, each of the first circuit layer 121, the second circuit layer 122, the third circuit layer 123, and the fourth circuit layer 124 may have a thickness of 15 μm to 20 μm.

The first circuit layer 121, the second circuit layer 122, the third circuit layer 123, and the fourth circuit layer 124 may include a conductive material. For example, the first circuit layer 121, the second circuit layer 122, the third circuit layer 123, and the fourth circuit layer 124 may include at least one metal material selected from gold (Au), silver (Ag), platinum (Pt), titanium (Ti), tin (Sn), copper (Cu), and zinc (Zn). Preferably, the first circuit layer 121, the second circuit layer 122, the third circuit layer 123, and the fourth circuit layer 124 may be formed of copper (Cu) having high electrical conductivity and relatively low cost.

On the other hand, the first circuit layer 121, the second circuit layer 122, the third circuit layer 123, and the fourth circuit layer 124 can be formed using the typical circuit board manufacturing process such as Additive Process, Subactive Process, MSAP (Modified Semi Additive Process), and SAP (Semi Additive Process), and detailed explanations are omitted here.

The circuit board includes a through electrode. For example, the circuit board includes a through electrode passing through the insulating layer and electrically connecting circuit layers disposed on different layers.

For example, the through electrode includes a first through electrode 131 passing through the first insulating layer 111. The first through electrode 131 may electrically connect the first circuit layer 121 and the second circuit layer 122.

In addition, the through electrode includes a second through electrode 132 passing through the second insulating layer 112. The second through electrode 132 may electrically connect the first circuit layer 121 and the third circuit layer 123.

In addition, the through electrode includes a third through electrode 133 passing through the third insulating layer 113. The third through electrode 133 may electrically connect the second circuit layer 122 and the fourth circuit layer 124.

In addition, the circuit board includes a protective layer. The protective layer may be disposed on an uppermost side or a lowermost side of the circuit board. The protective layer may protect a surface of a circuit layer or an insulating layer disposed on an uppermost side or a lowermost side of the circuit board.

Preferably, the protective layer may include a first protective layer 141 disposed on an upper surface of the second insulating layer 112. The first protective layer 141 may protect an upper surface of the second insulating layer 112 and an upper surface of the third circuit layer 123. In addition, the first protective layer 141 may include a first opening (not shown) overlapping at least a portion of an upper surface of the third circuit layer 123 in a thickness direction. The first opening may be formed to correspond to a mounting position of an electronic device.

In addition, the protective layer may include a second protective layer 142 disposed on a lower surface of the third insulating layer 113. The second protective layer 142 may protect a lower surface of the third insulating layer 113 and a lower surface of the fourth circuit layer 124. In addition, the second protective layer 142 may include a second opening (not shown) overlapping at least a portion of a lower surface of the fourth circuit layer 124 in a thickness direction. The second opening may be formed to correspond to a mounting position of an electronic device or a connection position with an external substrate.

In this case, the first protective layer 141 and the second protective layer 142 may be solder resist, but are not limited thereto.

Hereinafter, a layer structure of a circuit layer and a surface roughness thereof according to an embodiment will be described in detail.

In this case, the layer structure of the circuit layer may vary according to a method of manufacturing the circuit board. For example, the circuit layer may have different numbers of layers according to the method of manufacturing the circuit board.

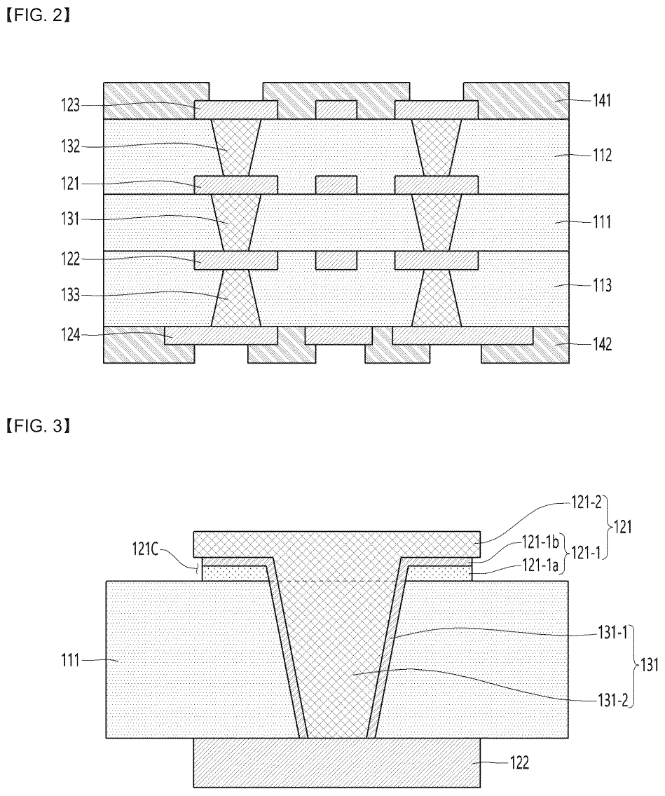

FIG. 3 is a view for explaining a layer structure of a circuit layer according to a first embodiment, and FIG. 4 is a view for explaining a layer structure of a circuit layer according to a second embodiment.

Hereinafter, any one of the first circuit layer 121 to the fourth circuit layer 124 will be mainly described. For example, hereinafter, a layer structure of the first circuit layer 121 will be described. However, a layer structure of the second circuit layer 122, the third circuit layer 123, and the fourth circuit layer 124 may correspond to a layer structure of the first circuit layer 121 described below.

Accordingly, hereinafter, the first insulating layer 111 will be referred to as an insulating layer, the first circuit layer 121 will be referred to as a circuit layer, and the first through electrode 131 will be referred to as a through electrode.

Referring to FIG. 3, the circuit board of the first embodiment may be manufactured by the MSAP method.

Meanwhile, hereinafter, it has been described that the circuit layer includes first to third metal layers.

In this case, the circuit layer may include a first layer and a second layer.

In addition, the first layer of the circuit layer may mean a first metal layer and a second metal layer to be described below. In addition, the second layer of the circuit layer may mean a third metal layer to be described below.

Hereinafter, the first to third metal layers of the circuit layer will be mainly described.

Meanwhile, the circuit board includes an insulating layer 111, a circuit layer 121, and a through electrode 131.

The circuit layer 121 may include a first metal layer 121-1 and a second metal layer 121-2.

The first metal layer 121-1 of the circuit layer 121 may be disposed on an upper surface of the insulating layer 111. The first metal layer 121-1 of the circuit layer 121 may mean a seed layer of the circuit layer 121.

In this case, the circuit layer 121 is manufactured by an MSAP process. Accordingly, the first metal layer 121-1 of the circuit layer 121 may be formed of a plurality of layers.

Preferably, the first metal layer 121-1 of the circuit layer 121 may include a first-first metal layer 121-1a and a first-second metal layer 121-1b.

The first-first metal layer 121-1a of the first metal layer 121-1 of the circuit layer 121 may be disposed on an upper surface of the insulating layer 111. The first-first metal layer 121-1a of the first metal layer 121-1 of the circuit layer 121 may mean a copper foil layer disposed on the upper surface of the insulating layer 111. For example, the first-first metal layer 121-1a of the first metal layer 121-1 of the circuit layer 121 may mean a copper foil.

The first-second metal layer 121-1b of the first metal layer 121-1 of the circuit layer 121 may be disposed on the first-first metal layer 121-1a. For example, the first-second metal layer 121-1b of the first metal layer 121-1 of the circuit layer 121 may be formed on the first-first metal layer 121-1a by electroless plating. Preferably, the first-second metal layer 121-1b of the first metal layer 121-1 of the circuit layer 121 may be a chemical copper plating layer.

The second metal layer 121-2 of the circuit layer 121 is disposed on the first metal layer 121-1 of the circuit layer 121. For example, the second metal layer 121-2 of the circuit layer 121 is disposed on the first-second metal layer 121-1b of the first metal layer 121-1 of the circuit layer 121. For example, the second metal layer 121-2 of the circuit layer 121 may be an electroplating layer formed by electroplating the first-second metal layer 121-1b with a seed layer.

Meanwhile, the through electrode 131 may penetrate the insulating layer 111. For example, the through electrode 131 may be formed by filling an inside of the through hole penetrating the insulating layer 111 with a conductive material. In this case, the through electrode 131 may be formed simultaneously in a process of forming the circuit layer 121.

Preferably, the through electrode 131 includes a first metal layer 131-1 corresponding to the first metal layer 121-1 of the circuit layer 121. Preferably, the first metal layer 131-1 of the through electrode 131 may correspond to the first-second metal layer 121-1b of the first metal layer 121-1 of the circuit layer 121.

Specifically, the first-second metal layer 121-1b of the first metal layer 121-1 of the circuit layer 121 and the first metal layer 131-1 of the through electrode 131 may refer to one layer formed by a chemical copper plating process. However, the first-second metal layer 121-1b of the first metal layer 121-1 of the circuit layer 121 and the first metal layer 131-1 of the through electrode 131 may be classified according to an arrangement position of the chemical copper plating layer.

For example, in one chemical copper plating layer, the first-second metal layer 121-1b of the first metal layer 121-1 of the circuit layer 121 may refer to a portion of the circuit layer 121 in contact with the first-first metal layer 121-1a of the first metal layer 121-1.

For example, in one chemical copper plating layer, the first metal layer 131-1 of the through electrode 131 may refer to a portion in contact with an inner wall of a through hole penetrating the insulating layer 111.

Meanwhile, the through electrode 131 may include a second metal layer 131-2. The second metal layer 131-2 of the through electrode 131 may correspond to the second metal layer 121-2 of the circuit layer 121.

Preferably, the through electrode 131 includes a second metal layer 131-2 corresponding to the second metal layer 121-2 of the circuit layer 121. That is, the second metal layer 121-2 of the circuit layer 121 and the second metal layer 131-2 of the through electrode 131 may mean one layer formed by electroplating the chemical copper plating layer as a seed layer. However, the second metal layer 121-2 of the circuit layer 121 and the second metal layer 131-2 of the through electrode 131 may be classified according to an arrangement position of the electroplating layer.

For example, the second metal layer 131-2 of the through electrode 131 may refer to a portion of one electroplating layer disposed within the through hole of the insulating layer 111. For example, the second metal layer 121-2 of the circuit layer 121 may refer to a portion of one electroplating layer disposed outside the through hole.

Meanwhile, the circuit layer of the circuit board of the second embodiment shown in FIG. 4 may have a different number of layers from the circuit layer of the circuit board of the first embodiment shown in FIG. 3.

For example, the through electrode of the circuit board of the second embodiment may have substantially the same structure as the through electrode of the circuit board of the first embodiment.

However, the circuit layer 121 of the circuit board of the second embodiment may have a different number of layers from the circuit layer of the circuit board of the first embodiment.

For example, the circuit layer 121 of the circuit board of the second embodiment includes a first metal layer 121-1 and a second metal layer 121-2.

In this case, the first metal layer 121-1 of the circuit layer of the circuit board of the first embodiment includes a first-first metal layer 121-1a and a first-second metal layer 121-1b.

Alternatively, the first metal layer 121-1 of the circuit layer 121 of the circuit board of the second embodiment may be formed of a single layer. For example, the circuit layer 121 of the circuit board of the second embodiment may include only the first-second metal layer 121-1b in the first metal layer of the first embodiment.

That is, the circuit board of the second embodiment may be manufactured by a SAP method. And, in a process of forming the circuit layer by the SAP method, the copper foil layer or the copper foil corresponding to the first-first metal layer 121-1a disposed on a surface of the insulating layer may be removed. Accordingly, in the circuit board of the second embodiment, the first metal layer corresponding to the seed layer may include only the first-second metal layer 121-1b corresponding to the chemical copper plating layer. In addition, the first metal layer 121-1 corresponding to the first-second metal layer 121-1b of the second embodiment may be in direct contact with the upper surface of the insulating layer 111.

Accordingly, when the circuit layer 121 is manufactured by the MSAP method, a thickness of the first metal layer 121-1 of the circuit layer 121 is in a range of 2.5 μm to 3.5 μm.

In addition, when the circuit layer 121 is manufactured by the SAP method, a thickness of the first metal layer 121-1 of the circuit layer 121 is in a range of 0.3 μm to 1.5 μm.

Specifically, the thickness of the first-first metal layer 121-1a may be in the range of 1 μm to 3.2 μm, and the thickness of the first-second metal layer 121-1b may be in the range of 0.3 μm to 1.5 μm.

Hereinafter, the circuit layer 121 manufactured by the MSAP method will be described. However, the circuit layer 121 of the circuit board of the embodiment is not limited to having a layer structure manufactured by the MSAP method, and may have a layer structure manufactured by the SAP method.

A side surface of the first metal layer 121-1 and a side surface of the second metal layer 121-2 may have a step. For example, a step may be provided at a boundary between a side surface of the first metal layer 121-1 and a side surface of the second metal layer 121-2. For example, a leftmost end of a left side surface of the first metal layer 121-1 and a leftmost end of a left side surface of the second metal layer 121-2 may be located on different vertical lines. The step may be referred to as an undercut formed at the lower end of a side surface of the first metal layer 121-1. Hereinafter, a step between the side surface of the first metal layer 121-1 and the side surface of the second metal layer 121-2 will be described as an undercut.

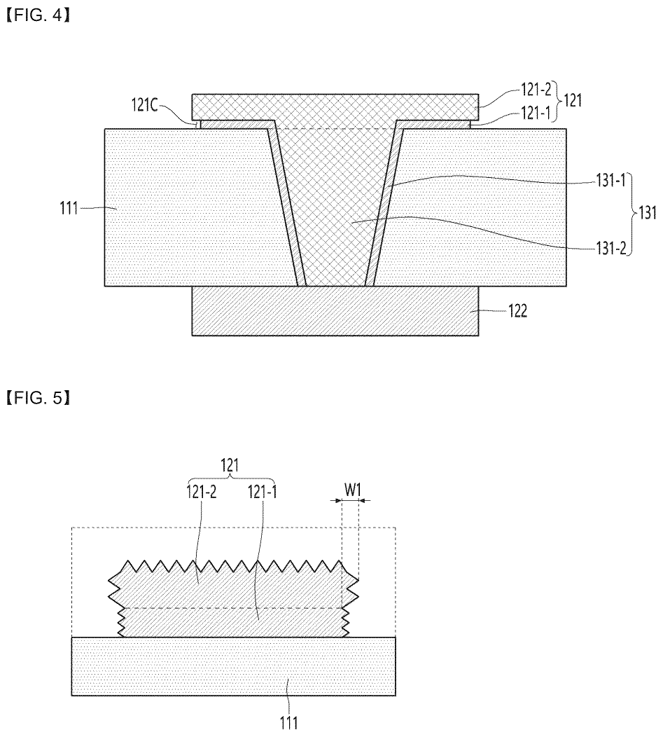

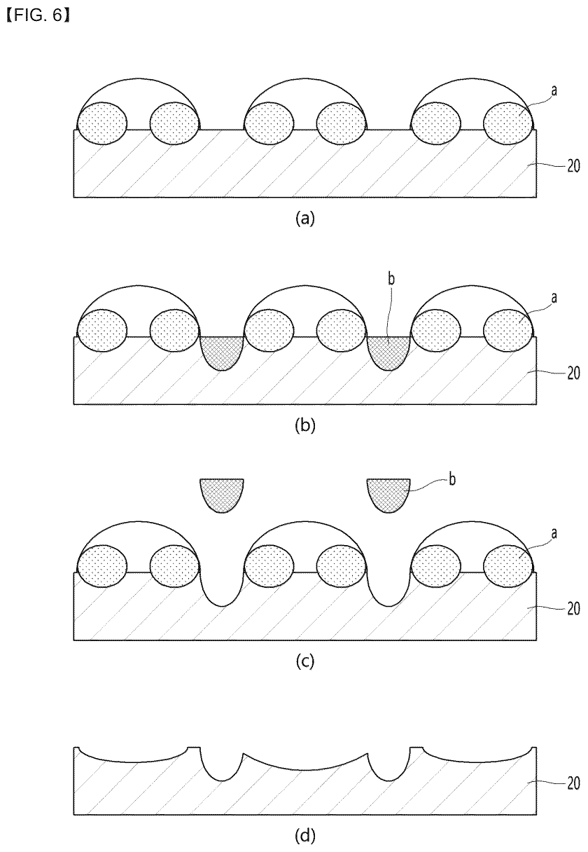

FIG. 5 is a view showing a circuit layer according to an embodiment in more detail.

Referring to FIG. 5, the circuit layer 121 includes a first metal layer 121-1 and a second metal layer 120-2.

In addition, an arithmetic average roughness Ra of the surface of the circuit layer 121 of the embodiment may be 0.2 μm or less. For example, the arithmetic average roughness Ra of the surface of the circuit layer 121 of the embodiment may be 0.1 μm or less.

Specifically, the arithmetic average roughness Ra of the surface of the circuit layer 121 of the embodiment may have a range of 0.05 μm to 0.2 μm. Preferably, the arithmetic average roughness Ra of the surface of the circuit layer 121 of the embodiment may have a range of 0.08 μm to 0.18 μm. More preferably, the arithmetic average roughness Ra of the surface of the circuit layer 121 of the embodiment may have a range of 0.09 μm to 0.15 μm.

For example, a ten-point average roughness (Rz) of the surface of the circuit layer 121 of the embodiment may be 1 μm or less. For example, a ten-point average roughness (Rz) of the surface of the circuit layer 121 of the embodiment may be 0.8 μm or less. For example, a ten-point average roughness (Rz) of the surface of the circuit layer 121 of the embodiment may be 0.6 μm or less.

Specifically, the ten-point average roughness Rz of the surface of the circuit layer 121 of the embodiment may have a range of 0.1 μm to 1.0 μm. Preferably, the ten-point average roughness Rz of the surface of the circuit layer 121 of the embodiment may have a range of 0.15 μm to 0.8 μm. More preferably, the ten-point average roughness Rz of the surface of the circuit layer 121 of the embodiment may have a range of 0.15 μm to 0.6 μm.

In this case, if the arithmetic average roughness Ra or the ten-point average roughness Rz of the surface of the circuit layer 121 is less than the above-described range, resistance of the circuit layer may increase. Also, if the arithmetic average roughness Ra or the ten-point average roughness Rz of the surface of the circuit layer 121 is less than the above-described range, adhesion with an additionally stacked insulating layer may not be secured. Also, if the arithmetic average roughness Ra or the ten-point average roughness Rz of the surface of the circuit layer 121 is greater than the above-described range, signal transmission loss may increase due to a skin effect. For example, if the arithmetic average roughness Ra or ten-point average roughness Rz of the surface of the circuit layer 121 is greater than the above-described range, a circuit board suitable for high frequency applications may not be provided.

In this case, the arithmetic average roughness Ra and the ten-point average roughness Rz of the surface of the circuit layer 121 may represent the surface roughness of the second metal layer 121-2 of the circuit layer 121. For example, the arithmetic average roughness Ra and the ten-point average roughness Rz of the surface of the circuit layer 121 may mean the surface roughness of the upper and side surfaces of the second metal layer 121-2 of the circuit layer 121.

Alternatively, the arithmetic average roughness Ra and the ten-point average roughness Rz of the surface of the circuit layer 121 may mean the surface roughness of the first metal layer 121-1 and the second metal layer 121-2. For example, the arithmetic average roughness Ra and the ten-point average roughness Rz of the surface of the circuit layer 121 may mean an average surface roughness of all of the side surface of the first metal layer 121-1, the upper surface of the second metal layer 121-2, and the side surface of the second metal layer 121-2.

However, in general, a size of crystal grains of a metal layer formed by electroplating is smaller than a size of crystal grains of a metal layer formed by chemical copper. For example, when an etching process of the first metal layer 121-1 is performed, a size of crystal grains of the first metal layer 121-1 removed by the etching solution is small, and accordingly, the surface roughness of the side surface of the first metal layer 121-1 may be smaller than the surface roughness of the upper surface and side surface of the second metal layer 121-2.

In this case, the surface roughness of the circuit layer 121 of the embodiment is lower than that of the circuit layer 20 of the comparative example. Accordingly, a transmission loss of the circuit layer according to the embodiment is lower than a transmission loss of the circuit layer 20 of the comparative example.

That is, results of testing a transmission loss of the circuit layer according to an embodiment are shown in Table 1 below.

TABLE 1

| | Transmission loss(dB/in), strip line | | |
|---|---|---|---|
| | 20 GHz | 30 GHz | 40 GHz |
| Embodiment | −1.49 | −1.77 | −2.04 |
| Comparative example | −1.77 | −2.12 | −2.46 |

Referring to Table 1, it was confirmed that the signal transmission loss of the comparative example under a condition of transmitting a signal of 20 GHz was −1.77. In addition, it was confirmed that the embodiment had a signal transmission loss of −1.49, which was lower than the comparative example. In addition, it was confirmed that the signal transmission loss of the comparative example under the condition of transmitting the signal of 30 GHz was −2.12. In addition, it was confirmed that the embodiment had a signal transmission loss of −1.77, which was lower than the comparative example.

In addition, it was confirmed that the signal transmission loss of the comparative example under the condition of transmitting the signal of 40 GHz was −2.46. In addition, it was confirmed that the embodiment had a signal transmission loss of −2.04, which was lower than the comparative example.

As described above, the embodiment allows the surface roughness of the circuit layer 121 to have a lower value than that of the comparative example. Accordingly, the embodiment may reduce the signal transmission loss of the circuit layer 121. Accordingly, signal characteristics may be improved. In addition, the embodiment may provide a circuit board suitable for high frequency applications.

Meanwhile, an embodiment may provide the circuit layer 121 having a depth smaller than that of the comparative example.

For example, the embodiment allows the surface roughness of the circuit layer 121 to be smaller than that of the circuit layer of the comparative example through a composition of the etching solution, and also allows ae depth of the undercut formed on the circuit layer 121 to be smaller than that of the circuit layer of the comparative example.

Specifically, the circuit layer 121 includes a first metal layer 121-1 and a second metal layer 121-2.

In addition, the embodiment may change a composition of the etching solution for etching the first metal layer 121-1, so that an undercut with a smaller depth than the comparative example may be included.

For example, an undercut 121C or a recess portion can be formed on a side surface of the first metal layer 121-1 of the circuit layer 121 of the embodiment. A depth W1 of the undercut 121C or the recess portion can be 4 μm or less. For example, a depth W1 of the undercut 121C or the recess portion may be 3 μm or less.

Specifically, the depth W1 of the undercut 121C of the circuit layer 121 of the embodiment may have a range of 0.5 μm to 4 μm. Preferably, the depth W1 of the undercut 121C of the circuit layer 121 of the embodiment may have a range of 0.5 μm to 3.5 μm. More preferably, the depth W1 of the undercut 121C of the circuit layer 121 of the embodiment may have a range of 0.5 μm to 3.0 μm. This may be due to the composition of the etching solution described below. The etching solution will be described in detail in a description of a method for manufacturing a circuit board.

If the depth W1 of the undercut 121C exceeds 4/m, signal transmission loss may increase due to a difference in width between the upper and lower surfaces of the circuit layer 121. In addition, if the depth W1 of the undercut 121C exceeds 4/mm, a contact area between the circuit layer 121 and the insulating layer 111 may decrease, and thus the adhesion may decrease. In addition, in order for the depth W1 of the undercut 121C to be less than 0.5 mm, a composition ratio of the etching solution must be changed, and if the composition ratio of the etching solution is changed, it may be difficult to manage the etching solution. In addition, if the depth W1 of the undercut 121C is smaller than 0.5 mm, an etching rate of the first metal layer 121-1 may be significantly reduced, and thus a manufacturing time of the circuit board may increase or the yield may decrease.

As described above, the embodiment can reduce the depth of the undercut of the circuit layer 121 compared to the comparative example, and thus improve the electrical reliability and physical reliability of the circuit layer 121.

Meanwhile, a reason why the surface roughness of the circuit layer of the comparative example and the surface roughness of the circuit layer of the embodiment are different will be explained.

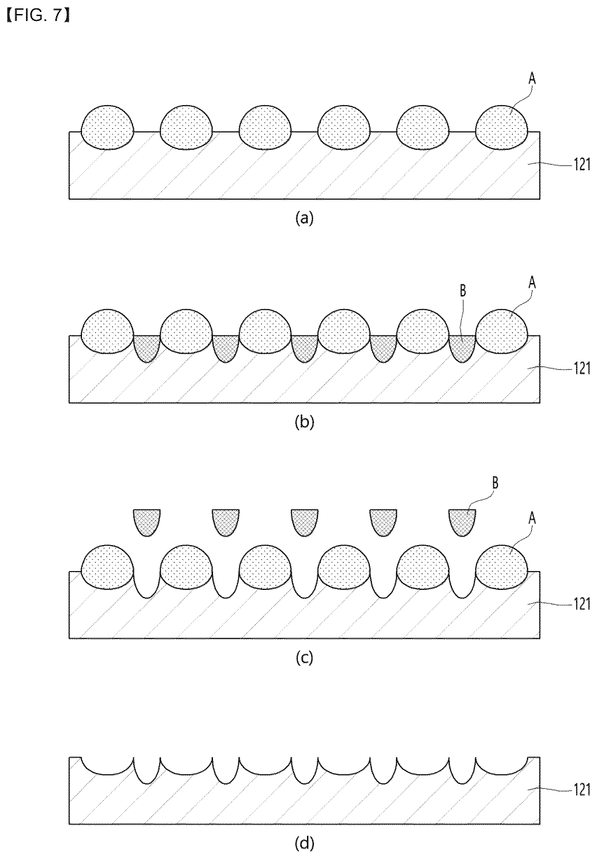

FIG. 6 is a view for explaining a process for forming a circuit layer of a comparative example and an etching solution of layer of a comparative example, and FIG. 7 is a view for explaining a process for forming a circuit layer of an embodiment and an etching solution of an embodiment.

Referring to FIG. 6 (a), the comparative example includes an inhibitor (a) in an etching solution (b) used in a process of forming the circuit layer 20.

The inhibitor (a) forms a film (or coating layer) on the surface of the circuit layer 20 through a coordination bond with copper ions and copper (II) ions during an etching of the first metal layer. The inhibitor (a) functions as a corrosion inhibitor.

Next, referring to (b) of FIG. 6, in the comparative example, a process of removing the first metal layer is performed using the etching solution (b) in a state in which a film (or coating layer) is formed on a surface of the circuit layer 20 by the inhibitor (a). In this case, the etching solution b is in contact with the surface of the circuit layer 20. Accordingly, a region of the surface of the circuit layer 20 where the film (or coating layer) is not formed by the inhibitor (a) is etched by the etching solution (b).

At this time, the inhibitor (a) used in the etching solution (b) of the comparative example is an azole-based material with a polymeric film structure containing a plurality of nitrogen atoms.

For example, the etching solution (b) of the comparative example may use an inhibitor (a) containing aminotetraazole. In addition, when the inhibitor (a) of the etching solution (b) and the copper (II) ion are coordinated, a chemical structure is shown in chemical formula 1 below.

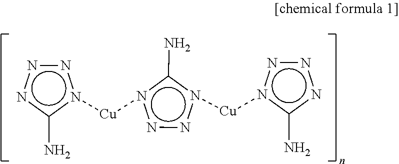

That is, when the inhibitor (a) of the comparative example and the copper (II) ion are coordinated, it can be confirmed that it has a polymer film structure as in the chemical formula 1.

In addition, the inhibitor (a) having the polymer film structure has a problem in that it is not uniformly adsorbed on the surface of the circuit layer 20.

Accordingly, as shown in (c) of FIG. 6, a region of the surface of the circuit layer 20 where the film (or coating layer) is not formed by the inhibitor (a) is etched relatively more.

Therefore, as shown in (d) of FIG. 6, the surface roughness of the circuit layer 20 of the comparative example has a value higher than the surface roughness of the embodiment.

That is, the inhibitor (a) used in the etching solution (b) of the comparative example includes tetraazole. At this time, although the tetraazole has a single molecular structure, it is arranged in a polymer form on the circuit layer 20. Accordingly, in the comparative example, the film (or coating layer) formed by the inhibitor (a) is not uniformly arranged on the surface of the circuit layer 20. Accordingly, in the comparative example, relatively more etching occurs in a region where the film (or coating layer) is not arranged, thereby resulting in high surface roughness.

Referring to (a) of FIG. 7, the etching solution (B) used in a process of forming the circuit layer 121 of the embodiment includes an inhibitor (A). At this time, the inhibitor (A) of the embodiment may include a material having a small molecular weight.

Preferably, the inhibitor (A) of the embodiment may be a material having a molecular weight of between 43 and 500. For example, the inhibitor (A) of the embodiment may be a primary amine containing only one amine group. Differently, the inhibitor (A) of the embodiment may include an amino acid. For example, the inhibitor (A) of the embodiment may include an amino acid selected from a group consisting of glycine, glutathione, and cysteine.

When the inhibitor (A) includes a primary amine, a film (or coating layer) can be uniformly formed on the surface of the circuit layer 121 by the inhibitor (A). Accordingly, when the inhibitor (A) includes a primary amine, uniform etching can be performed on the entire surface of the circuit layer 121 during etching of the first metal layer 121-1. For example, in the comparative example, there was a large difference between a portion of the surface of the circuit layer 20 where etching was not performed and a portion where etching was performed. In addition, the difference in etching increases the surface roughness of the circuit layer 20. In contrast, the embodiment can allow uniform etching to be performed on the entire region of the surface of the circuit layer 121. Accordingly, the embodiment can reduce surface roughness compared to the comparative example because uniform etching is performed on the entire surface.

That is, when the inhibitor (A) of the embodiment includes a primary amine, side etching of the circuit layer 121 can be effectively prevented in the etching process, and the copper wiring corresponding to the circuit layer 121 can be prevented from becoming thinner. For example, when a polyallylamine-based cationic polymer is used as the inhibitor (A), it is possible to more efficiently prevent the copper wiring from becoming thinner.

Meanwhile, when the inhibitor (A) includes an amino acid, hydrophilicity in an ionic solution can be improved due to a carboxyl group of the amino acid. Through this, when the inhibitor (A) includes an amino acid, a uniform film (or coating layer) can be formed on the surface of the circuit layer 121, so that uniform etching can be performed on the surface of the circuit layer 121. Accordingly, the embodiment may allow the surface roughness of the circuit layer 121 to have a lower value than that of the comparative example while preventing side etching of the circuit layer 121.

Accordingly, as shown in (b) and (c) of FIG. 7, an etching process can be performed by the etching solution (B) in a state where a uniform film (or coating layer) is formed on the surface of the circuit layer 121 by the inhibitor (A).

Therefore, as shown in (d) of FIG. 7, the embodiment can minimize a depth difference between a portion where etching is performed by the etching solution (B) and a portion where etching is not performed, compared to the comparative example. In addition, the surface roughness of the circuit layer 121 can be reduced compared to the comparative example by minimizing the depth difference.

Meanwhile, a specific composition of the etching solution (B) of the embodiment will be specifically described in a method for manufacturing a circuit board below.

FIG. 8 is a view showing a semiconductor package according to an embodiment.

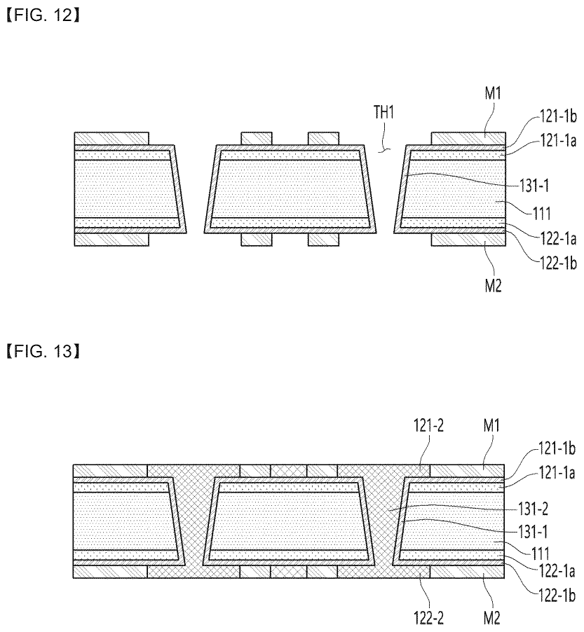

Referring to FIG. 12, the semiconductor package according to an embodiment includes the circuit board described with reference to the previous drawings.

The circuit board includes a first protective layer 141 and a second protective layer 142. In addition, each of the first protective layer 141 and the second protective layer 142 includes an opening.

Meanwhile, the semiconductor package includes a first connection part 210 disposed in the opening of the first protective layer 141. For example, the first connection part 210 may be disposed on the third circuit layer 123 vertically overlapping the opening of the first protective layer 141.

The first connection part 210 may include a spherical shape. For example, a cross section of the first connection part 210 may have a circular shape or a semicircular shape. For example, a cross section of the first connection part 210 may have a partially or entirely rounded shape. For example, a cross-sectional shape of the first connection part 210 may be a flat surface on one side and a curved surface on the other side. The first connection part 210 may be a solder ball, but is not limited thereto.

A device 220 may be disposed on the first connection part 210. The device 220 may be a processor chip. For example, the device 220 may be any one of a central processor (e.g., CPU), a graphic processor (e.g., GPU), a digital signal processor, an encryption processor, a microprocessor, and a microcontroller. However, embodiments are not limited thereto, and the device 220 may be various types of passive devices or active devices such as a driver IC, a capacitor, and an inductor other than the processor chip.

A terminal 225 is formed at a lower surface of the device 220. In addition, the terminal 225 of the device 220 is connected to the first connection part 210. Accordingly, the device 220 may be electrically connected to the third circuit layer 123.

In this case, although it is illustrated that one device is mounted on a circuit board in the drawing, the embodiment is not limited thereto. For example, the semiconductor package according to an embodiment may include a first device and a second device disposed to be spaced apart from each other in a horizontal direction on one circuit board.

For example, a first device and a second device may be different types of application processors AP.

In this case, the first device and the second device may be spaced apart from each other by a predetermined separation distance in a horizontal direction on the circuit board. For example, a separation distance of the first device and the second device in a horizontal direction may be 150 μm or less. For example, a separation distance of the first device and the second device in a horizontal direction may be 120 μm or less. For example, a separation distance of the first device and the second device in a horizontal direction may be 100 μm or less.

Preferably, the separation distance of the first device and the second device in the horizontal direction may satisfy a range of 60 μm to 150 μm. More preferably, the separation distance of the first device and the second device in the horizontal direction may satisfy a range of 70 μm to 120 μm. More preferably, the separation distance of the first device and the second device in the horizontal direction may satisfy a range of 80 μm to 110 μm.

In this case, if the separation distance of the first device and the second device in the horizontal direction is less than 60 μm, a problem may occur in the operational reliability of the first device or the second device due to mutual interference between the first device and the second device. In addition, if the separation width of the first device and the second device in the horizontal direction is greater than 150 μm, a signal transmission distance between the first device and the second device may increase, and accordingly, a signal transmission loss may increase.

Meanwhile, the semiconductor package may include a molding layer 230. The molding layer 230 may be disposed on the circuit board to mold the device 220. The molding layer 230 may serve to protect the device 220. For example, the molding layer 230 may be an epoxy mold compound (EMC), but is not limited thereto.

Meanwhile, the molding layer 230 may have a low dielectric constant. Accordingly, the molding layer 230 may increase heat dissipation characteristics. To this end, the dielectric constant (Dk) of the molding layer 230 may be in a range of 0.2 to 10. Preferably, the dielectric constant of the molding layer 230 may be in a range of 0.5 to 5. More preferably, the dielectric constant of the molding layer 230 may be in a range of 0.8 to 5. Accordingly, in the embodiment, the molding layer 230 may have a low dielectric constant. Accordingly, the embodiment may increase the heat dissipation characteristics for heat generated by the device 220.

Meanwhile, the semiconductor package further includes a second connection part 240. The second connection part 240 may be disposed at a lowermost side of the circuit board. Preferably, the second protective layer 142 includes an opening. In addition, the second connection part 240 may be disposed in the opening of the second protective layer 142. Preferably, at least a portion of a lower surface of the fourth circuit layer 124 overlaps an opening of the second protective layer 142 in a thickness direction. In addition, the second connection part 240 may be disposed on a lower surface of the fourth circuit layer 124 overlapping an opening of the second protective layer 142 in a thickness direction. The second connection part 240 may be for connecting the semiconductor package to an external substrate (e.g., a main board of an electronic device).

Hereinafter, a method of manufacturing a circuit board according to an embodiment will be described.

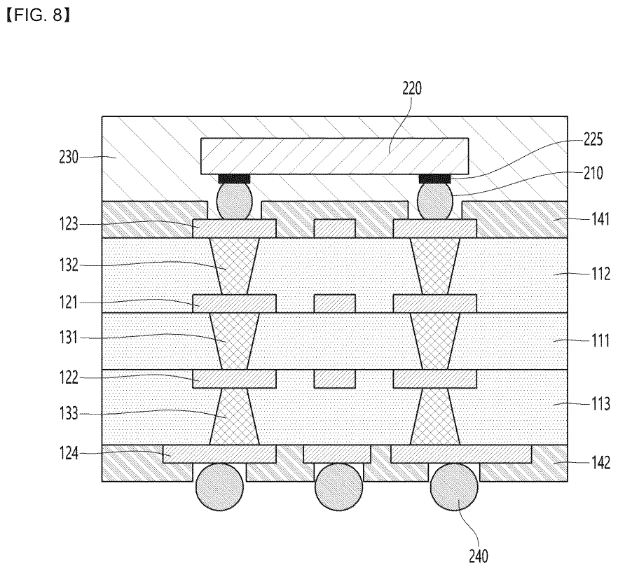

FIGS. 9 to 18 are views for explaining a method for manufacturing a circuit board according to an embodiment in order of process.

Referring to FIG. 9, an embodiment prepares a base material that is a basis for manufacturing a circuit board. For example, the base material may have a structure in which an insulating layer and a copper layer or copper foil are attached on the insulating layer.

Specifically, the base material of an embodiment may include a first insulating layer 111, a first-first metal layer 121a of the first circuit layer 121 disposed on the upper surface of the first insulating layer 111, and a first-first metal layer 122-1a of the second circuit layer 122 disposed on the lower surface of the first insulating layer 111.

Next, referring to FIG. 10, an embodiment may perform a process of forming through-holes TH1 penetrating upper and lower surfaces of the prepared base material. In this case, FIG. 10 may illustrate a method of manufacturing a circuit board by an MSAP process. Alternatively, when a circuit board is manufactured by an SAP process, a process of removing the first-first metal layer 121-1a of the first circuit layer 121 and the first-first metal layer 122-1a of the second circuit layer 122 may be performed.

The through hole TH1 may penetrate from an upper surface of the first-first metal layer 121-1a of the first circuit layer 121 to a lower surface of the first-first metal layer 122-1a of the second circuit layer 122.

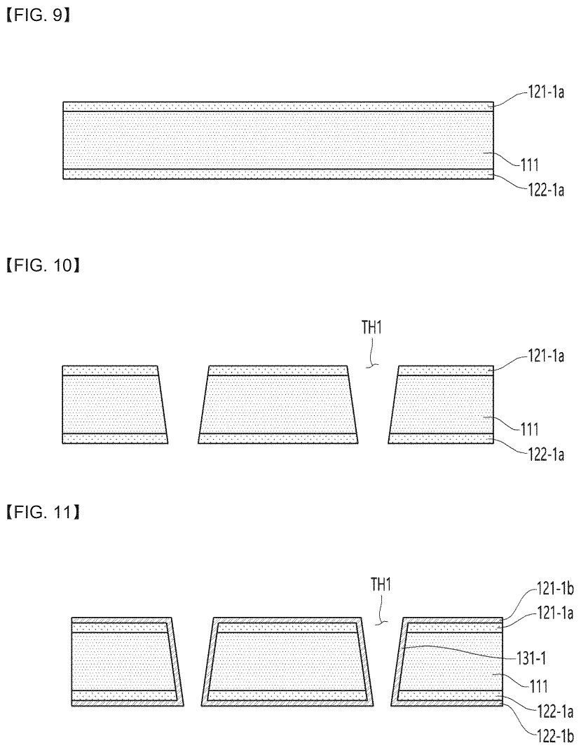

Next, referring to FIG. 11, in the embodiment, chemical copper plating may be performed to form a chemical copper plating layer.

In this case, the chemical copper plating layer is formed as substantially one layer, but may be classified as follows depending on a position.

That is, the chemical copper plating layer may include a first-second metal layer 121-1b of the first circuit layer 121 formed on the upper surface of the first-first metal layer 121-1a of the first circuit layer 121, a first-second metal layer 122-1b of the second circuit layer 122 formed on the lower surface of the first-first metal layer 122-1a of the second circuit layer 122, and a first metal layer 131-1 of the first through electrode 131 formed on an inner wall of the through hole TH1.

Next, as shown in FIG. 12, the embodiment may proceed with a process of forming a mask.

For example, the embodiment may proceed with a process of forming a first mask M1 on the upper surface of the first-second metal layer 121-1b of the first circuit layer 121. In this case, the first mask M1 may include an open portion. For example, the first mask M1 may include an open portion overlapping an arrangement region of the second metal layer 121-2 of the first circuit layer 121 and an arrangement region of the first through electrode 131 in a thickness direction.

In addition, the embodiment may proceed with a process of forming a second mask M2 on a lower surface of the first-second metal layer 122-1b of the second circuit layer 122. In this case, the second mask M2 may include an open portion. For example, the second mask M2 may include an open portion overlapping an arrangement region of the second metal layer 122-2 of the second circuit layer 122 and an arrangement region of the first through electrode 131 in a thickness direction.

Next, as shown in FIG. 13, the embodiment may form an electroplating layer that fills the open portion of the first mask M1, the open portion of the second mask M2, and the through hole TH1.

In this case, the electroplating layer may mean one layer substantially connected to each other, but may be divided into a plurality of portions as follows depending on a position.

The electroplating layer may include a second metal layer 121-2 of the first circuit layer 121 disposed in the open portion of the first mask M1. Also, the electroplating layer may include a second metal layer 122-2 of the second circuit layer 122 disposed in the open portion of the second mask M2. Also, the electroplating layer may include a second metal layer 131-2 of the first through electrode 131 disposed in the through hole TH1.

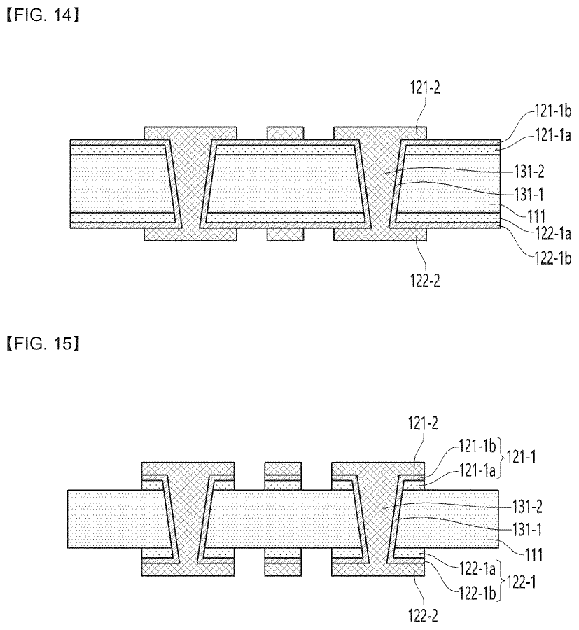

Next, as shown in FIG. 14, an embodiment may perform a process of removing the first mask M1 and the second mask M2.

In this case, as the first mask M1 is removed, a non-arrangement region of the second metal layer 121-2 of the first circuit layer 121 among the upper surfaces of the first-second metal layer 121-1b of the first circuit layer 121 may be exposed to an outside.

In addition, as the second mask M2 is removed, a non-arranged region of the second metal layer 122-2 of the second circuit layer 122 among the lower surfaces of the first-second metal layer 122-1b of the second circuit layer 122 may be exposed to an outside.

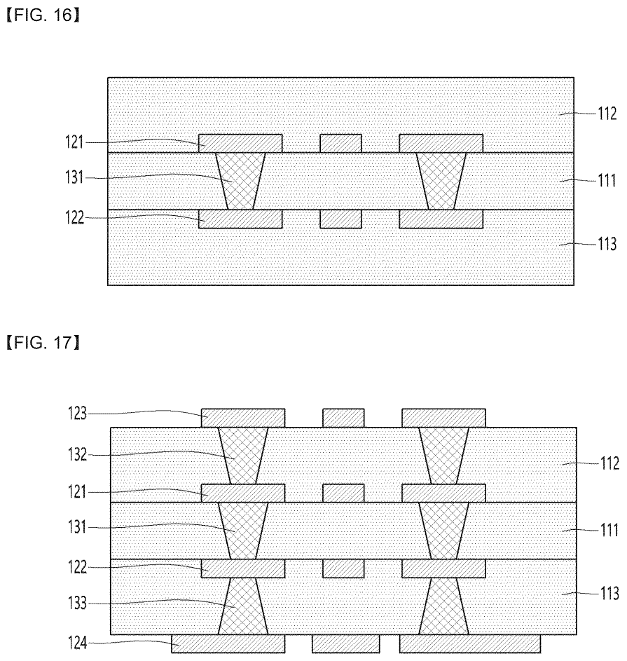

Next, referring to FIG. 15, the embodiment may proceed with an etching process of removing a region of the first metal layer (the first-first metal layer and the first-second metal layer) of the first circuit layer 121 that does not overlap in the thickness direction.

In addition, the embodiment may perform an etching process of removing a region of the first metal layer (first-first metal layer and first-second metal layer) of the second circuit layer 122 that does not overlap in the thickness direction.

In this case, the first circuit layer 121 and the second circuit layer 122 according to an embodiment are manufactured by the MSAP method, and accordingly, an etching thickness (or etching depth or etching amount) in an etching process may be 3.0 to 4.0 μm. That is, a thickness of each of the first metal layers of the first circuit layer 121 and the second circuit layer 20 is in a range of 2.5 to 3.5 μm, and accordingly, the etching thickness in the etching process may be set in a range of 3.0 to 4.0 μm, which is larger than the thickness.

In this case, the etching solution used in the process of etching the first metal layer of the embodiment may have a following composition.

The etching solution of an embodiment may be an etching solution for etching the circuit layer 121 manufactured by the MSAP method. For example, the etching solution described below may be an etching solution for etching the first metal layer 121-1 of the circuit layer 121 in a range of 3.0 to 4.0 μm. However, the embodiment is not limited thereto, and the etching solution described below may be used to etch the first metal layer of the circuit layer 121 manufactured by the SAP method in the range of 0.6 μm to 1.6 μm by using the etching solution described below or by changing the concentration or composition of the etching solution described below.

The etching solution of the embodiment includes acid. For example, the etching solution of the embodiment may include at least one acid selected from a group consisting of sulfuric acid, hydrochloric acid, and nitric acid. In this case, the first metal layer 121-1 includes an electroless plating layer. Accordingly, the embodiment uses sulfuric acid as a type of the acid. The sulfuric acid may secure a stable etching rate of a copper plating layer formed by electroless, and may secure stability of dissolved copper ions. That is, it is possible to increase the etching rate of the first metal layer 121-1 as an electroless plating layer by adjusting a concentration of sulfuric acid contained in the etching solution. If sulfuric acid is included in the etching solution, an exchange period of the etching solution, and processability may be secured accordingly. In addition, the sulfuric acid may prevent dissolved copper from being precipitated into copper sulfate. For example, by using the sulfuric acid, an etched copper may be re-attached to an unetched copper surface, or a copper sulfate crystal may prevent damage to the circuit layer. In addition, sulfuric acid may remove a copper oxide film on the surface of the first metal layer 121-1 to be etched, and may stabilize Cu2+ ions as an oxidizing agent.

In this case, a concentration of the acid in the etching solution may be in a range of 5 vol. % to 15 vol. %. If the concentration of the acid is smaller than 5 vol. %, the first metal layer 121-1 may not be stably etched. For example, if the concentration of the acid is smaller than 5 vol. %, an etching rate of the first metal layer 121-1 may be reduced, and this may result in a deterioration in etching characteristics. If the concentration of the acid is greater than 15 vol. %, the surface roughness of the circuit layer 121 may be greater than the surface roughness targeted in the embodiment. In addition, if the concentration of the acid is greater than 15 vol. %, a depth of the undercut 121C formed in the circuit layer 121 may increase.

Meanwhile, an oxidizing agent may be included in the etching solution of an embodiment. For example, the oxidizing agent may be hydrogen peroxide. For example, the etching solution may include an oxidizing agent of hydrogen peroxide selected from a group consisting of (NH₄)₂S₂O₈, MnO₂, KMnO₄, and K₂S₂O₈. The above oxidizing agent can increase the etching rate by re-oxidizing Cu(I) ions formed during etching into Cu(II).

The oxidizing agent may have a concentration in a range of 2 vol. % to 7 vol. % in the etching solution. If the concentration of the oxidizing agent is smaller than 2 vol. %, the etching rate of the first metal layer 121-1 may be lowered. In addition, if the concentration of the oxidizing agent exceeds 7 vol. %, there is a high possibility that reaction heat is generated, and thus, the depth of the undercut 121C formed in the circuit layer 121 may be increased.

In this case, an oxidation and etching reaction of the first metal layer 121-1, which is a copper plating layer, may be performed over following two times.

A first time is a copper oxidation reaction, which may be expressed as in reaction formula 1.

Cu(s)+H₂O₂(I)→CuO(s)+H₂O(I) [Reaction Formula 1]

A second time is a copper oxide film ionization reaction, which may be expressed as in Reaction formula 2.

CuO(s)+H₂SO₄(I)→Cu²⁺+SO₄²⁻+H₂O(I) [Reaction Formula 2]

In this case, as in Reaction Formula 1, an etching rate may be easily controlled according to the concentration adjustment of H2O2 as the copper oxidation reaction is a rate-determining reaction.

In addition, the etching solution may include oxidizing metal ions. For example, the etching solution may include copper (II) ions such as copper chloride, copper sulfate, and copper hydroxide. In addition, the etching solution may include iron (II) ions such as iron chloride, iron bromide, and iron sulfate. In this case, the oxidizing metal ions may be included in the etching solution in a range of 10 to 40 h/L.

At this time, when copper (II) ions are included in the etching solution above, the dissolved copper (II) ions do not function as an oxidizing agent, and this may prevent local corrosion of the first metal layer 121-1 while maintaining a stable etching rate.

In addition, when iron (II) ions are included in the etching solution, the iron (II) ions may function to oxidize copper constituting the first metal layer 121-1 and etch the copper. In this case, in an embodiment, since iron (II) ions are included in the etching solution, even if the etching solution penetrates into micropores of the first metal layer 121-1, oxidant deficiency may occur, thereby suppressing the etching function and minimizing the occurrence of undercuts. In addition, the iron (II) ion can significantly increase an etching rate difference between the first metal layer 121-1 and the second metal layer 121-2 in the process of etching the first metal layer 121-1, thereby lowering the surface roughness of the circuit layer 121 compared to the comparative example.

Meanwhile, an inhibitor may be included in the etching solution of the embodiment. The inhibitor allows the circuit layer 121 of the embodiment to have a small undercut 121C while having a lower surface roughness than that of the circuit layer 20 of the comparative example.

In this case, the inhibitor contained in the etching solution may include an amine group. Specifically, the inhibitor may include a primary amine containing only one amine group. Preferably, the inhibitor may include a primary amine having a molecular weight satisfying a range of 43 to 500.

At this time, the primary amine of aliphatic and aryl used as an inhibitor of the embodiment may include any of Chemical Formulas 2 to 8.

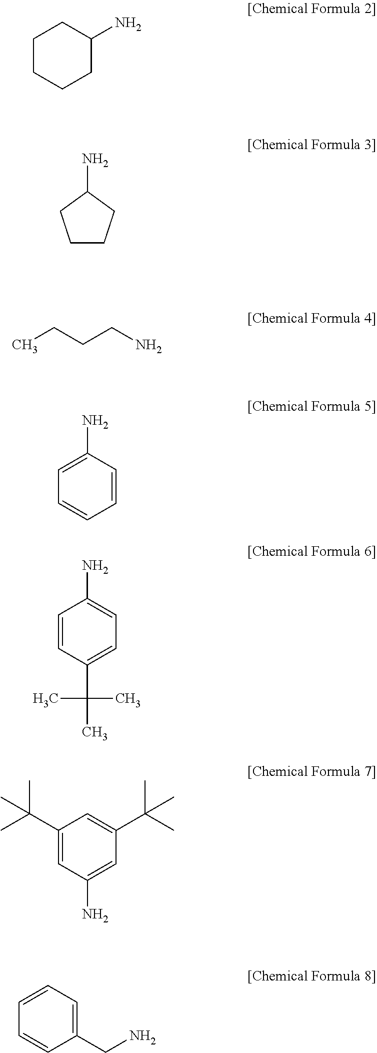

That is, when a primary amine is used as the inhibitor of the embodiment, the primary amine may include any one of cyclohexyl amine represented by chemical formula 2, cyclopentyl amine represented by chemical formula 3, n-butyl amine, pentyl amine, hexyl amine represented by chemical formula 4, . . . (C₄-C₁₀)—NH₂, aniline represented by chemical formula 5, 4-tert-butylaniline represented by chemical formula 6, 3,5-di-tert-butylaniline represented by chemical formula 7, and benzyl amine represented by chemical formula 8. Specifically, the inhibitor of the embodiment includes a primary amine. At this time, if a length of the alkyl chain of the amine used as the inhibitor becomes too long, the miscibility of the etching solution may decrease. In addition, if a material used as an inhibitor contains two or more amine groups, the inhibitor forms a precipitate in the etching solution by binding to copper ions, and thus management of the etching solution may not be easy. Accordingly, in the embodiment, a primary amine, i.e., a material containing only one amine group, is used as the inhibitor. At this time, when a primary amine is used as the inhibitor, a uniform film (or coating layer) can be formed on the surface of the circuit layer (121) in the etching process, and thus an uniformity of the etching can be secured while minimizing the side etching. In addition, when a polyallylamine-based cationic polymer is used, thinning of the circuit layer due to etching can be efficiently managed.

In this case, when the primary amine is used as the inhibitor, the inhibitor may be added to the etching solution in a concentration of 0.05 vol. % to 5.0 vol. %. In this case, if the concentration of the inhibitor is smaller than 0.05 vol. %, there can be a problem that the primary amine cannot function as the inhibitor. In addition, if the concentration of the inhibitor exceeds 5.0 vol. %, there can be a problem that the film (or coating layer) may not be uniformly formed on the surface of the circuit layer 121 by the inhibitor. In addition, if the film (or coating layer) is not uniformly formed, an area of the film (or coating layer) may increase, and accordingly, a difference in an amount of etching in a region where the film (or coating layer) is disposed and a region where the film (or coating layer) is not disposed may increase. In addition, if the difference in the amounts of etching increases, a problem in which the surface roughness of the circuit layer increases as in the comparative example may occur.

Meanwhile, the etching solution of an embodiment may include an amino acid as the inhibitor. For example, an inhibitor including at least one amino acid selected from glycine, glutathione, and cysteine may be added to the etching solution of the embodiment. The amino acid includes a carboxyl group. In addition, the carboxyl group may function to increase hydrophilicity in an ionic solution. Accordingly, when the inhibitor including the amino acid is added to the etching solution, a uniform film (or coating layer) may be formed on the surface of the circuit layer 121 and accordingly, surface roughness of the circuit layer 121 may be lowered than that of the comparative example.

In this case, when an amino acid is used as the inhibitor, a concentration of the inhibitor in the etching solution may range from 0.01 vol. % to 3.0 vol. %. If the concentration of the inhibitor composed of the amino acid is smaller than 0.01 vol. %, the amino acid may not function as the inhibitor. In addition, if the concentration of the inhibitor composed of the amino acid is greater than 3.0 vol. %, it may be difficult to form a uniform film (or coating layer) on the surface of the circuit layer 121.

Meanwhile, the etching solution may include an ionic surfactant. The ionic surfactant may be added to the etching solution at a concentration of 200 ppm to 700 ppm (parts per million). If the concentration of the ionic surfactant in the etching solution is smaller than 200 ppm, the ionic surfactant may not perform the function described below. In addition, if the concentration of the ionic surfactant exceeds 700 ppm, bubbles may be generated in the etching solution, and thus, it may be difficult to manage the etching solution.

The ionic surfactant may have anionic and cationic properties. Preferably, the ionic surfactant may be a cationic surfactant acting in a positive form in an environment in which strong acid is used.

The ionic surfactant may reduce surface tension of the etching solution while improving wettability between the circuit layers 121. That is, the ionic surfactant may support the etching solution penetrate into the surface of the circuit layer 121 and thus may function to remove a surface oxide. In this case, the ionic surfactant has an effect of acting faster even in a small amount compared to a nonionic surfactant. In addition, in the embodiment, a low molecular surfactant is applied as the ionic surfactant.

Accordingly, the embodiment may increase the etching rate by allowing the etching solution to quickly penetrate even a fine circuit layer (for example, a circuit layer having a line width of 20 μm and a spacing of 20 μm).

In this case, a cationic surfactant is used as the surfactant in the embodiment. In addition, the cationic surfactant may include any one of Chemical Formulas 9 to 13.

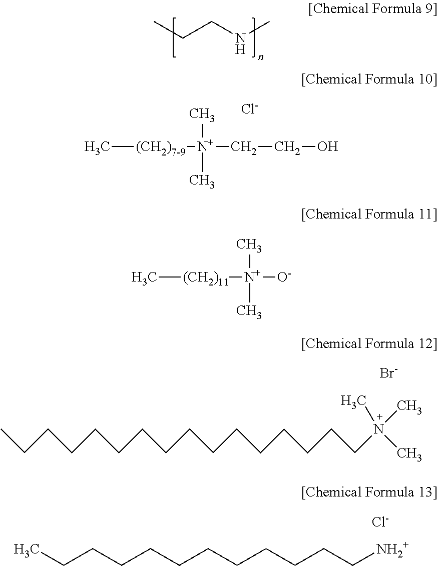

Specifically, the cationic surfactant may be any one of Polyethylenimine (PEI) represented by Chemical Formula 9, C8-10 alkyl hydroxyethyl, dimethylammonium chloride, alkylamidodimethyl propylamine represented by Chemical Formula 10, alkyl dimethyl amine oxide represented by Chemical Formula 11, Cetrimonium bromide represented by Chemical Formula 12, and Dodecyl ammonium chloride represented by Chemical Formula 13.

The cationic surfactant has cationic properties in an acidic environment, and may be used in a linear form rather than a branched form so as not to be affected by steric hindrance.

Meanwhile, the etching solution may further contain an oxidizing stabilizer. The oxidizing stabilizer may contain any one of phenolsulfonic acid, benzenesulfonic acid, and cresol sulfonic acid. The oxidizing stabilizer may have a function of preventing an oxidizing agent such as hydrogen peroxide from being excessively decomposed. The oxidizing stabilizer may be added to the etching solution at a concentration of 0.05 vol. % to 1.0 vol. %.

As described above, unlike the etching solution of the comparative example, the etching solution of the embodiment includes an inhibitor and an ionic surfactant.

In addition, the inhibitor includes a primary amine or an amino acid, not a tetraazole or a triazole group as in the comparative example. In addition, when a primary amine is used as the inhibitor, a length of an aliphatic chain of the primary amine may be C4-C10.

Accordingly, the embodiment can use an inhibitor having a primary amine group to quickly form a film (or coating layer) on the surface of the circuit layer 121, while allowing the first metal layer 121-1 having a relatively large grain boundary area to be etched faster than the second metal layer 121-2.

At this time, since the aliphatic chain of the primary amine functioning as the inhibitor has a length of C4-C10, the influence of steric hindrance can be minimized, and since only one nitrogen atom having an unshared electron pair capable of reacting with a copper ion is included, a low-density film can be uniformly formed on the surface of the circuit layer 121.

Accordingly, in the embodiment, the surface roughness of the circuit layer can be reduced compared to the comparative example, and accordingly, the signal transmission loss can be minimized.

In addition, the amino acid used as the inhibitor is zwitterionic, which may act as a buffer in an etching solution. In addition, the amino acid includes a hydroxyl group, and the hydroxyl group may easily control a concentration of H+. Accordingly, stability of the etching solution may be secured, and thus the depth of the undercut may be reduced while reducing the surface roughness of the circuit layer.

That is, the amino group of the amino acid acts as an inhibitor by forming an inhibitor with copper, and the carboxylic acid on other side can act as a proton buffer. Accordingly, the concentration of H+ may be easily maintained at an appropriate level. Accordingly, the surface roughness of the circuit layer may be reduced. In addition, the depth of the undercut of the circuit layer may be minimized.

In addition, a low molecular weight ionic surfactant is used as the ionic surfactant included in the etching solution, and thereby uniform etching can be performed even on a high-density circuit. That is, the low molecular weight ionic surfactant functions as a surfactant quickly in a small amount compared to a non-ionic surfactant. Accordingly, in the embodiment, in the process of etching the circuit layer 121, the etching process can be completed before the etching solution penetrates into the first metal layer 121-1 that overlaps the second metal layer 121-2 in the thickness direction. Accordingly, the embodiment can minimize the depth of the undercut of the circuit layer 121.

In addition, the embodiment can prevent damage to the second metal layer 121-2 by using the low molecular weight ionic surfactant, thereby reducing the surface roughness of the circuit layer 121.

Accordingly, the embodiment performs an etching process with the etching solution, and accordingly, the surfaces of the first circuit layer 121 and the second circuit layer 122 after the etching process can have an arithmetic average roughness Ra and a ten-point average roughness Rz that are lower than the arithmetic average roughness Ra and the ten-point average roughness Rz of the circuit layer of the comparative example, as described above.

Next, as shown in FIG. 16, the embodiment may proceed with a process of stacking the second insulating layer 112 on the upper surface of the first insulating layer 111. In addition, the embodiment may proceed with a process of stacking the third insulating layer 113 on the lower surface of the first insulating layer 111.

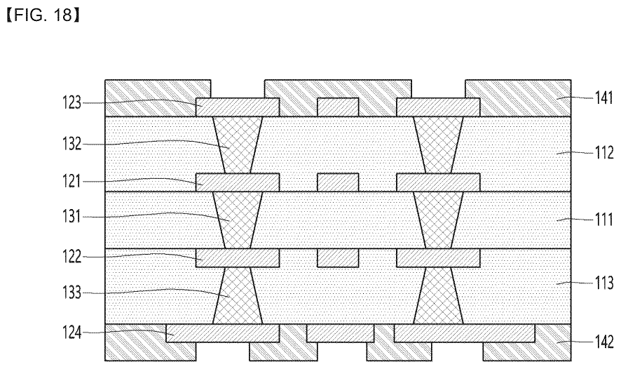

Next, referring to FIG. 17, the embodiment may perform a process of forming a second through electrode 132 passing through the second insulating layer 112 and the third circuit layer 123 disposed on an upper surface of the second insulating layer 112. In this case, the process of forming the third circuit layer 123 may be the same as the process of forming the first circuit layer 121. Accordingly, the surface roughness of the third circuit layer 123 may correspond to the surface roughness of the first circuit layer 121. To this end, in a process of stacking the second insulating layer 112, a copper foil layer (not shown) or a copper foil (not shown) may be disposed on the upper surface of the second insulating layer 112.

In addition, the embodiment may perform a process of forming a third through electrode 133 penetrating the third insulating layer 113 and a fourth circuit layer 124 disposed on a lower surface of the third insulating layer 1131. In this case, a process of forming the fourth circuit layer 124 may be the same as a process of forming the second circuit layer 122. Accordingly, a surface roughness of the fourth circuit layer 124 may correspond to a surface roughness of the second circuit layer 122. To this end, in a process of stacking the third insulating layer 113, a copper foil layer (not shown) or a copper foil (not shown) may be disposed on a lower surface of the third insulating layer 112.

Next, as shown in FIG. 18, the embodiment may perform a process of forming a first protective layer 141 on an upper surface of the second insulating layer 112. In addition, the embodiment may perform a process of forming a second protective layer 142 on a lower surface of the third insulating layer 113. In addition, the embodiment may perform a process of forming a first opening of the first protective layer 141 overlapping at least a portion of an upper surface of the third circuit layer 123 in a thickness direction. In addition, the embodiment may perform a process of forming a second opening of the second protective layer 142 overlapping at least a portion of a lower surface of the fourth circuit layer 124 in a thickness direction.

A circuit layer of the embodiment includes a first metal layer and a second metal layer disposed on the first metal layer. The first metal layer may be a seed layer, and the second metal layer may be an electroplating layer formed with the first metal layer as a seed layer.

In this case, in the embodiment, during a process of forming the circuit layer, an etching process is performed to remove a portion of an entire region of the first metal layer that does not overlap with the second metal layer in a thickness direction. In this case, an etching solution in the embodiment contains an inhibitor and an ionic surfactant of a different type from the inhibitor and ionic surfactant of the etching solution of the comparative example.

Specifically, the inhibitor of the embodiment includes a primary amine or amino acid, not a tetra azole or triazole used in the comparative example. In addition, if a primary amine is used as the inhibitor, a length of an aliphatic chain of the primary amine may be C4-C10. Accordingly, the embodiment allows the first metal layer having a relatively large grain boundary area to be etched faster than the second metal layer while allowing a film (or coating layer) to be formed quickly on a surface of the circuit layer by using an inhibitor having a primary amine group.

In addition, since the aliphatic chain of the primary amine functioning as the inhibitor has a length of C4-C10, an influence of steric hindrance can be minimized. Furthermore, the inhibitor contains only one nitrogen atom having an unshared electron pair that can interact with a copper ion, thereby uniformly forming a low-density film on the surface of the circuit layer.

Accordingly, in the embodiment, a surface roughness of the circuit layer can be lowered compared to the comparative example, and the signal transmission loss resulting therefrom can be minimized.

In addition, the amino acid used as the inhibitor is a zwitterionic, which can act as a buffer in the etching solution. In addition, the amino acid contains a hydroxyl group, and the hydroxyl group can easily control a concentration of H+. Accordingly, stability of the etching solution can be secured, and a depth of an undercut can be reduced while reducing the surface roughness of the circuit layer.

That is, an amino group of the amino acid can act as an inhibitor by forming an inhibitor with copper, while a carboxylic acid at other side can act as a proton buffer. Through this, a concentration of H+ can be easily maintained at an appropriate level. As a result, a surface roughness of the circuit layer can be reduced. In addition, a depth of an undercut of the circuit layer can be minimized.

In addition, a low molecular weight ionic surfactant is used as the ionic surfactant included in the etching solution in the embodiment. As a result, in the embodiment, uniform etching can be performed even on a high-density circuit. That is, the low molecular weight ionic surfactant can quickly function as a surfactant in a small amount compared to a non-ionic surfactant. In the embodiment, the penetration of the etching solution into a region overlapping the second metal layer in a thickness direction can be minimized in a process of etching the first metal layer. Accordingly, the embodiment can minimize the depth of the undercut of the circuit layer.

In addition, the embodiment can prevent damage to the second metal layer by using the low molecular weight ionic surfactant, thereby reducing the surface roughness of the circuit layer.

In conclusion, in the embodiment, an inhibitor including a primary amine or an amino acid and a low molecular weight ionic surfactant are added to the etching solution for etching the first metal layer. Accordingly, the embodiment can reduce the surface roughness of the surface of the circuit layer compared to the comparative example. Accordingly, the embodiment can reduce the signal transmission loss of the circuit layer compared to the comparative example. Accordingly, the embodiment can improve the signal characteristics of the circuit board. Furthermore, the embodiment can provide a circuit board suitable for high frequency applications.

Furthermore, the embodiment includes an undercut of a smaller depth than the comparative example. Accordingly, the embodiment can further improve product reliability of the circuit board.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

1-10. (canceled)

11. A circuit board comprising:
an insulating layer; and
a circuit layer disposed on the insulating layer,
wherein a side surface of the circuit layer includes a first side surface and a second side surface facing each other,
wherein the first side surface of the circuit layer includes a concave portion recessed in a horizontal direction toward the second side surface, and
wherein a width of the concave portion in the horizontal direction is smaller than a height of the concave portion in a vertical direction.

12. The circuit board of claim 11, wherein the width of the concave portion in the horizontal direction satisfies a range of 0.5 μm to 3.0 μm.

13. The circuit board of claim 11, wherein the circuit layer includes:
a first metal layer disposed on the insulating layer; and
a second metal layer disposed on the second metal layer, and
wherein the concave portion is a step between a side surface of the first metal layer and a side surface of the second metal layer.

14. The circuit board of claim 13, wherein a surface roughness of the side surface of the first metal layer is different from that of the side surface of the second metal layer.

15. The circuit board of claim 14, wherein the surface roughness of the side surface of the first metal layer is smaller than that of the side surface of the second metal layer.

16. The circuit board of claim 15, wherein an arithmetic average roughness Ra of an upper surface and the side surface of the second metal layer has a range of 0.05 μm to 0.2 μm.

17. The circuit board of claim 15, wherein a ten-point average roughness Rz of an upper surface and the side surface of the second metal layer has a range of 0.1 μm to 1.0 μm.

18. The circuit board of claim 13, wherein a thickness of the first metal layer is smaller than that of the second metal layer.

19. The circuit board of claim 13, wherein the first metal layer has a thickness in a range of 2.5 μm to 3.5 μm.

20. The circuit board of claim 19, wherein the first metal layer includes:
a first-first metal layer disposed on the insulating layer; and
a first-second metal layer disposed on the first-first metal layer,
wherein the second metal layer is disposed on the first-second metal layer, and
wherein a thickness of the first-first metal layer is greater than that of the first-second metal layer.

21. The circuit board of claim 11, further comprising:
a semiconductor device disposed on the circuit layer.

22. The circuit board of claim 21, further comprising:
a burying insulating layer filling the semiconductor.

23. A circuit board comprising:
an insulating layer; and
a circuit layer disposed on the insulating layer,
wherein the circuit layer above includes:
a first portion having a first width in a horizontal direction; and
a second portion disposed on the first portion and having a second width in the horizontal direction greater than the first width, and
wherein a distance layer in the horizontal direction between a side surface of the second portion at one side of the circuit layer and a side surface of the first portion at the one side of the circuit is less than or equal to a thickness of the first portion in a vertical direction.

24. The circuit board of claim 23, wherein the distance satisfies a range of 0.5 μm to 3.5 μm.

25. The circuit board of claim 24, wherein the distance satisfies a range of 0.5 μm to 3.0 μm.

26. The circuit board of claim 23, wherein a thickness of the first portion in the vertical direction is smaller than a thickness of the second portion in the vertical direction.

27. The circuit board of claim 26, wherein the thickness of the first portion in the vertical direction has a range of 2.5 μm to 3.5 μm.

28. The circuit board of claim 25, wherein the distance is smaller than the thickness of the first portion in the vertical direction.

29. The circuit board of claim 23, wherein a surface roughness of the side surface of the first portion is smaller than that of the side surface of the second portion.
